(19) United States
(12) Patent Application Publication
(10) Pub. No.: US 2013/0000713 A1
(43) Pub. Date: Jan. 3, 2013

(54) NANOSTRUCTURE AND MANUFACTURING METHOD THEREOF, AND SOLAR CELL INCLUDING THE SAME

(75) Inventors: Seung Hwan Ko, Daejeon (KR); Hyun Wook Kang, Daejeon (KR); Junyeob Yeo, Daejeon (KR); Sukjoon Hong, Daejeon (KR); Hyung Jin Sung, Daejeon (KR)

(73) Assignee: Korea Advanced Institute of Science and Technology, Daejeon (KR)

(21) Appl. No.: 13/274,416

(22) Filed: Oct. 17, 2011

(30) Foreign Application Priority Data
Jun. 29, 2011 (KR) 10-2011-0063970

(51) Int. Cl. H01L 31/0224; B05D 3/00; B05D 1/38; B32B 5/02; B05D 5/00; B82Y 99/00

(52) U.S. Cl. 136/256; 428/107; 427/261; 977/773; 977/948

(57) ABSTRACT

A manufacturing method of a nanostructure according to an exemplary embodiment of the present invention includes: adhering a plurality of first nanoparticles on a substrate to form a nanoseed layer; growing the nanoseed layer on the substrate to form a plurality of nanowires; adhering a plurality of second nanoparticles to the side surface of the nanowires to form a nanoshell layer; and growing the nanoshell layer to form a plurality of nanobranches.

### CROSS-REFERENCE TO RELATED APPLICATION

This application claims priority to and the benefit of Korean Patent Application No. 10-2011-0063970 filed in the Korean Intellectual Property Office on Jun. 29, 2011, the entire contents of which are incorporated herein by reference.

### BACKGROUND OF THE INVENTION

(a) Field of the Invention

The present invention relates to a nanostructure, a manufacturing method thereof, and a solar cell including the same.

(b) Description of the Related Art

In general, a nanostructure has various functionalities in electrical, electronic, optical, and engineering applications such that research thereof has been actively performed as a core element in application fields such as energy, displays, sensors, and bionics.

Particularly, a metal oxide such as TiO₂ and ZnO may have a shape of a nanoparticle, a nanowire, or a nanotube, and a nanostructure of a desired shape and structure for various applications may be formed as the importance of a technique for integrating a nanostructure of other shapes is increased. Particularly, the nanostructure is largely applied as a photoelectrode of a dye sensitized solar cell (DSSC).

The dye sensitized solar cell includes a conductive transparent electrode, a porous photoelectrode absorbed with a dye and made of titanium oxide (TiO₂) nanoparticles, an electrolyte, and an opposite electrode, and the electrons inside the dye that are excited by visible rays are injected to the titanium oxide TiO₂ of the porous photoelectrode and are moved. However, the porous photoelectrode made of titanium oxide (TiO₂) has a poor depletion layer such that an energy loss due to hole and electron recombination generated while the electron is moved in the porous photoelectrode is increased, thereby decreasing energy conversion efficiency.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention provides a nanostructure that increases solar cell energy conversion efficiency, a manufacturing method thereof, and a solar cell including the same.

A nanostructure according to an exemplary embodiment of the present invention includes: a plurality of nanowires formed at predetermined intervals on a substrate; a plurality of nanobranches enclosing side surfaces of the nanowires; and a plurality of sub-nanobranches enclosing side surfaces of the nanobranches.

The nanowires, the nanobranches, and the sub-nanobranches may include zinc oxide.

The nanowires may be formed in a direction perpendicular to the surface of the substrate.

The nanobranches may be formed by removing a polymer from the nanowires and by progressing a hydrothermal reaction, and the nanobranches are extended in the side direction of the nanowires.

The sub-nanobranches may be formed by repeating the hydrothermal reaction, and the sub-nanobranches are extended in the side direction of the nanobranches.

A manufacturing method of a nanostructure according to an exemplary embodiment of the present invention includes: adhering a plurality of first nanoparticles on a substrate to form a nanoseed layer; growing the nanoseed layer on the substrate to form a plurality of nanowires; adhering a plurality of second nanoparticles to the side surface of the nanowires to form a nanoshell layer; and growing the nanoshell layer to form a plurality of nanobranches.

The forming of the nanoseed layer may include filling a seed solution including a plurality of first nanoparticles into a seed container, and positioning a substrate inside the seed container to form the nanoseed layer on the substrate.

The forming of the nanowires may include soaking the substrate formed with the nanoseed layer in a precursor solution including the polymer, and progressing a hydrothermal reaction for the nanoseed layer.

A plurality of nanowires may be formed at predetermined intervals on the substrate.

The method may further include removing the polymer from the nanowires after forming a plurality of nanowires.

The nanowires may be heated to remove the polymer.

The nanobranches may be formed by growing the nanoshell layer in the side surface of the nanowires.

The method may further include progressing a hydrothermal reaction for the nanobranches to form a plurality of sub-nanobranches at the side surface of the nanobranches.

A solar cell according to an exemplary embodiment of the present invention includes: a photoelectrode made of a nanostructure including a plurality of nanowires formed at predetermined intervals on a substrate, a plurality of nanobranches enclosing the side surface of the nanowires, a plurality of sub-nanobranches enclosing the side surface of the nanobranches, and a dye absorbed to the photoelectrode; an opposite electrode facing the photoelectrode; and an electrolyte positioned between the photoelectrode and the opposite electrode.

The nanowires, the nanobranches, and the sub-nanobranches may include zinc oxide.

According to the present invention, a nanostructure includes a plurality of nanowires formed at predetermined intervals on a substrate and a plurality of nanobranches enclosing the side surface of the nanowires, thereby increasing the specific surface area for absorbing light, and resultantly the light absorption ratio may be improved.

Further, the dye sensitized solar cell having the photoelectrode including the nanostructure according to an exemplary embodiment of the present invention is manufactured such that the loss of electrons generated by light reaction is reduced, and thereby the energy conversion efficiency of the dye sensitized solar cell may be improved.

The nanostructure according to an exemplary embodiment of the present invention is applied to various electronic devices such as a photosensor and a display such that the performance thereof may be improved.

### BRIEF DESCRIPTION OF THE DRAWINGS

FIG. 1 is a side view of a nanostructure according to an exemplary embodiment of the present invention.

FIG. 2 to FIG. 5 are views sequentially showing a manufacturing method of a nanostructure according to an exemplary embodiment of the present invention.

FIG. 6 shows SEM photos of a nanostructure according to an exemplary embodiment of the present invention, wherein FIG. 6(a) is a SEM photo showing an axis direction growth of nanowires when a hydrothermal reaction is repeated 1 to 3 times, FIG. 6(b) is a SEM photo showing a side growth of nanobranches in a case that a nanoshell layer is not formed after removing a polymer, and FIG. 6(c) is a SEM photo showing a side growth of nanobranches in a case that a nanoshell layer is formed after removing a polymer.

FIG. 7 is an explanation view of a solar cell including a nanostructure according to an exemplary embodiment of the present invention.

FIG. 8 is a view of curves of an open circuit voltage (V) and a short circuit current density (J) of a solar cell according to an exemplary embodiment of the present invention.

FIG. 9 is a view of a characteristic of a solar cell shown in FIG. 8.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

Descriptions of parts not related to the present invention are omitted, and like reference numerals designate like elements throughout the specification.

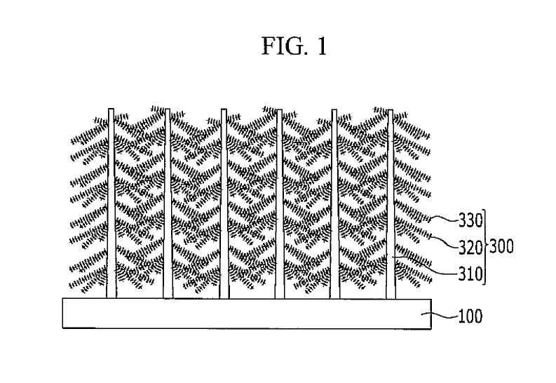

A nanostructure 300 according to an exemplary embodiment of the present invention will now be described with reference to FIG. 1.

FIG. 1 is a side view of the nanostructure 300 according to an exemplary embodiment of the present invention.

As shown in FIG. 1, the nanostructure 300 according to an exemplary embodiment of the present invention includes a plurality of nanowires 310 formed at a predetermined interval on a substrate 100, a plurality of nanobranches 320 enclosing a side surface of the nanowires 310, and a plurality of sub-nanobranches 330 enclosing the side surface of the nanobranches 320.

The nanowires 310, the nanobranches 320, and the sub-nanobranches 330 are formed of zinc oxide (ZnO), and the nanowires 310 are formed in a direction perpendicular to a surface of the substrate 100. A plurality of nanowires 310 further include a polymer of hexamethylenetetramine (HMTA) and polyethylenimine (PEI), and the polymer interrupts the side growth of a nanoseed layer 31 and does not interrupt the axis direction growth of the nanoseed layer 31 when progressing a hydrothermal reaction such that a plurality of nanowires 310 are formed at the predetermined interval on the substrate 100.

The polymer is removed from a nanoshell layer 32 enclosing the nanowires 310 when progressing the hydrothermal reaction such that the side growth and the axis direction growth of the nanoshell layer 32 both progress. Accordingly, the nanobranches 320 are grown on all sides of a plurality of nanowires 310.

Also, the polymer is removed at the side surface of the grown nanobranches 320 such that the side growth and the axis direction growth of the nanoshell layer 33 remaining at the nanobranches 320 both progress. Accordingly, the sub-nanobranches 330 are grown on all sides of a plurality of nanobranches 320.

An entire surface area per unit mass or a unit volume of any particle is referred as a specific surface area, and as described above, the specific surface area of the nanostructure 300 is increased by the nanowires 310, the nanobranches 320, and the sub-nanobranches 330.

As described above, the nanostructure 300 according to an exemplary embodiment of the present invention is made of the nanowires 310, the nanobranches 320, and the sub-nanobranches 330 such that the specific surface area may be maximized, and thereby a dye deposition ratio and an absorption ratio may be improved, resultantly energy conversion efficiency may be improved.

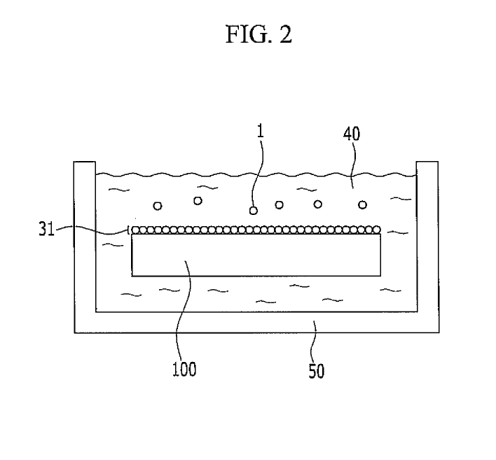

A manufacturing method of a nanostructure 300 according to an exemplary embodiment of the present invention will be described with reference to FIG. 2 to FIG. 5.

FIG. 2 to FIG. 5 are views sequentially showing a manufacturing method of a nanostructure 300 according to an exemplary embodiment of the present invention.

In a manufacturing method of a nanostructure 300 according to an exemplary embodiment of the present invention, as shown in FIG. 2, a seed solution 40 including a plurality of first nanoparticles 1 made of zinc oxide (ZnO) is filled in a seed container 50. This seed solution 40 is a solution in which the first nanoparticle 1 manufactured by mixing sodium hydroxide (NaOH) and zinc acetate (Zn(OAc)₂) is dispersed in ethanol.

Also, the substrate 100 is positioned inside the seed container 50 to form the nanoseed layer 31 on the substrate 100. A plurality of first nanoparticles 1 are adhered to the substrate 100, thereby forming the nanoseed layer 31.

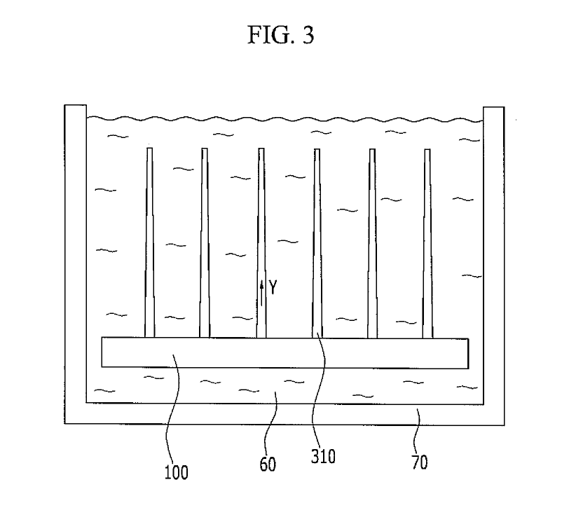

Next, as shown in FIG. 3, the nanoseed layer 31 on the substrate 100 is grown to form a plurality of nanowires 310. For this, the substrate 100 formed with the nanoseed layer 31 is positioned in a pressure container 70 filled with a precursor solution 60 including zinc nitrate hexahydrate (Zn(NO₃)₂.6H₂O), hexamethylenetetramine (HMTA), polyethylenimine (PEI), and deionized water.

A hydrothermal reaction is progressed in the pressure container 70 for 3 to 7 hours at a temperature of 65 degrees to 95 degrees such that the nanoseed layer 31 is grown to form a plurality of nanowires 310.

The polymer of hexamethylenetetramine (HMTA) and polyethylenimine (PEI) formed on the surface of the substrate 100 interrupts the side growth of the nanoseed layer 31 and does not interrupt the axis direction (Y) growth of the nanoseed layer 31 such that a plurality of nanowires 310 are formed at a predetermined interval on the substrate 100.

The hydrothermal reaction is repeated such that a plurality of nanowires 310 may be grown in the direction perpendicular to the surface of the substrate 100.

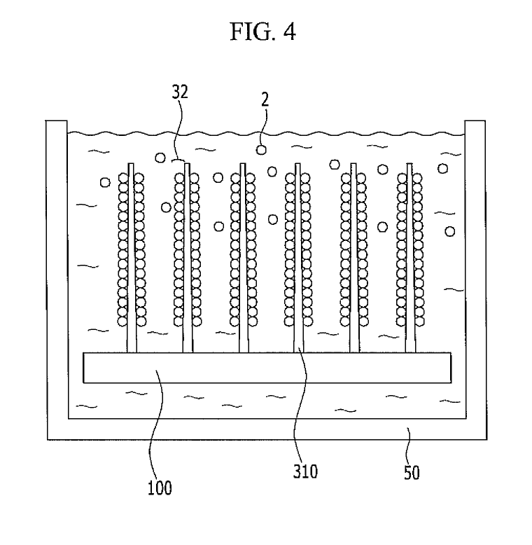

Next, as shown in FIG. 4, the nanowires 310 are heated at a temperature of 350 degrees for 10 minutes to remove the polymer included in the nanowires 310. Also, a plurality of second nanoparticles 2 are adhered to the side surface of the nanowires 310 to form the nanoshell layer 32.

For this, the substrate 100 is soaked in a seed solution in which a plurality of second nanoparticles 2 made of zinc oxide (ZnO) are dispersed in ethanol. Accordingly, the plurality of second nanoparticles enclose and are adhered to the side surface of the plurality of nanowires 310 to form the nanoshell layer 32.

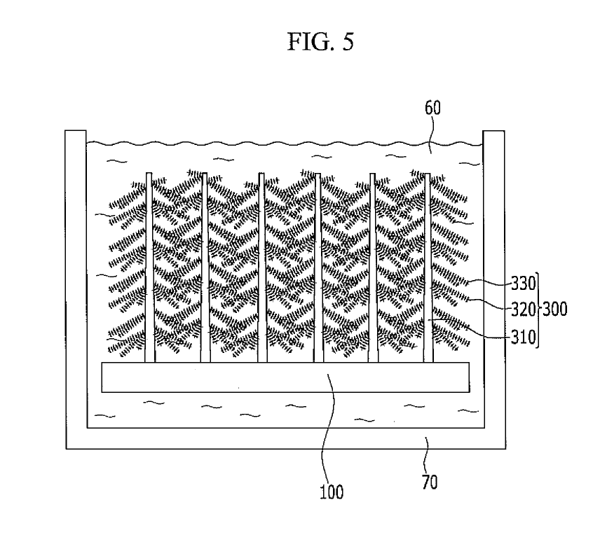

Next, as shown in FIG. 5, the nanoshell layer 32 is grown to form a plurality of nanobranches 320. For this, the substrate 100 formed with the nanoshell layer 32 is positioned in a pressure container 70 filled with a precursor solution including zinc nitrate hexahydrate (Zn(NO₃)₂.6H₂O), hexamethylenetetramine (HMTA), polyethylenimine (PEI), and deionized water.

The hydrothermal reaction is progressed at a temperature of 65 degrees to 95 degrees for 3 to 7 hours in the pressure container 70 such that the nanoshell layer 32 is grown in the side surface of the nanowires 310 to form a plurality of nanobranches 320.

The polymer is removed from the nanoshell layer 32 and the side growth and the axis direction growth of the nanoshell layer 32 are progressed such that the nanobranches 320 are grown on all side surfaces of a plurality of nanowires 310.

Also, the above hydrothermal reaction is repeated to grow a plurality of sub-nanobranches 330 in various directions on the side surface of the nanobranches 320 such that the specific surface area may be widened.

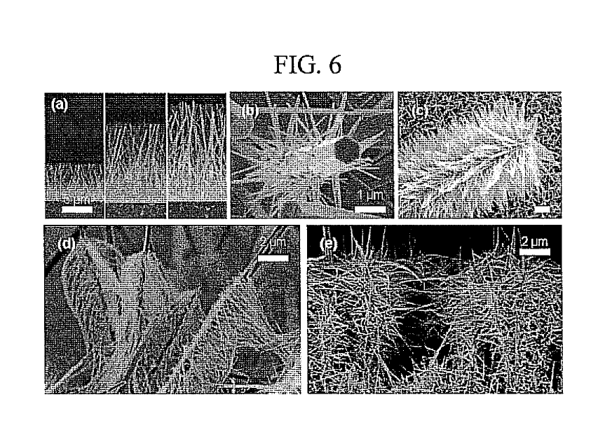

FIG. 6 shows SEM photos of a nanostructure according to an exemplary embodiment of the present invention, wherein FIG. 6(a) is a SEM photo showing an axis direction growth of a nanowires of which a hydrothermal reaction is repeated 1 to 3 times, FIG. 6(b) is a SEM photo showing side growth of a nanobranch in a case that a nanoshell layer is not formed after removing a polymer, and FIG. 6(c) is a SEM photo showing side growth of a nanobranch in a case that a nanoshell layer is formed after removing a polymer.

As shown in FIG. 6(a), it may be confirmed that the axis direction length of the nanowires is increased as the hydrothermal reaction is repeated, and as shown in FIG. 6(b) and FIG. 6(c), it may be confirmed that the nanobranches are closely grown in a case that the nanoshell layer is formed compared with a case that the nanoshell layer is not formed.

FIG. 6(d) is a SEM photo showing a side growth of nanobranches in a case that a polymer is not removed, and FIG. 6(e) is a SEM photo showing side growth of nanobranches in a case that a polymer is removed.

As shown in FIG. 6(d) and FIG. 6(e), in the case that the polymer is removed in the nanoshell layer 32, it may be confirmed that the nanoshell layer 32 is grown into the nanobranches 320 of a hierarchically dense structure.

As described above, the manufacturing method of the nanostructure 300 according to an exemplary embodiment of the present invention forms the nanobranches 320 and the sub-nanobranches 330 after removing the polymer adhered to the nanowires 310 such that the nanobranches 320 and the sub-nanobranches 330 are grown larger.

Accordingly, the specific surface area may be maximally widened such that the dye deposition ratio and the light absorption ratio may be improved, and thereby the energy conversion efficiency may be improved.

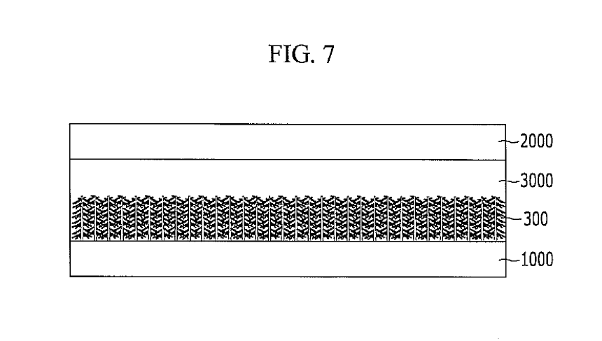

FIG. 7 is an explanation view of a solar cell including a nanostructure according to an exemplary embodiment of the present invention.

As shown in FIG. 7, a solar cell including the nanostructure according to an exemplary embodiment of the present invention includes a photoelectrode 1000 made of the nanostructure 300 and the dye absorbed thereto, an opposite electrode 2000 facing the photoelectrode 1000, and an electrolyte 3000 between the photoelectrode 1000 and the opposite electrode 2000. The dye absorbs the visible rays and is injected to the nanostructure 300 in the photoelectrode 1000 to move the electrons, thereby functioning as a solar cell.

The nanostructure 300 includes a plurality of nanowires 310 formed at a predetermined interval on a substrate 100, a plurality of nanobranches 320 enclosing a side surface of the nanowires 310, and a plurality of sub-nanobranches 330 enclosing the side surface of the nanobranches 320.

The nanowires 310, the nanobranches 320, and the sub-nanobranches 330 are formed of zinc oxide (ZnO), and the nanowires 310 are formed in a direction perpendicular to a surface of the substrate 100. A plurality of nanowires 310 further include a polymer of hexamethylenetetramine (HMTA) and polyethylenimine (PEI), and the polymer interrupts the side growth of the nanoseed layer 31 and does not interrupt the axis direction growth of the nanoseed layer 31 when progressing a hydrothermal reaction such that a plurality of nanowires 310 are formed at the predetermined interval on the substrate 100.

The polymer is removed from the nanoshell layer 32 enclosing the nanowires 310 when progressing the hydrothermal reaction such that the side growth and the axis direction growth of the nanoshell layer 32 both progress. Accordingly, the nanobranches 320 are grown on all sides of a plurality of nanowires 310.

Also, the polymer is removed at the side surface of the grown nanobranches 320 such that the side growth and the axis direction growth of the nanoshell layer 33 remaining at the nanobranches 320 both progress. Accordingly, the sub-nanobranches 330 are grown on all sides of a plurality of nanobranches 320.

Therefore, the specific surface area of the nanostructure 300 is widened by the nanowires 310, the nanobranches 320, and the sub-nanobranches 330.

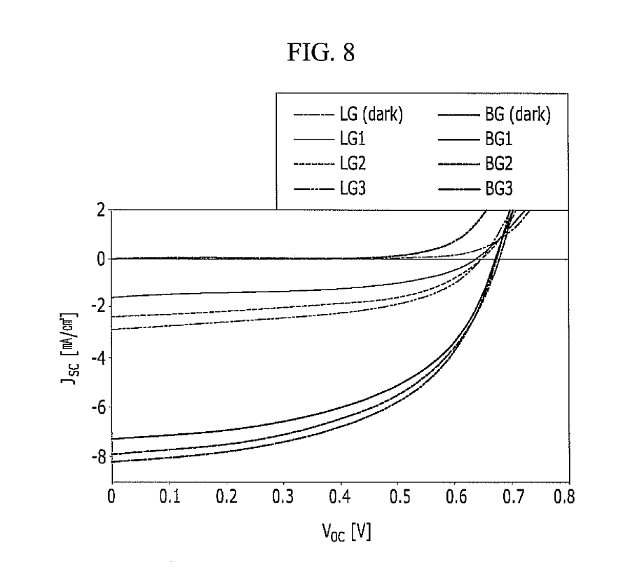

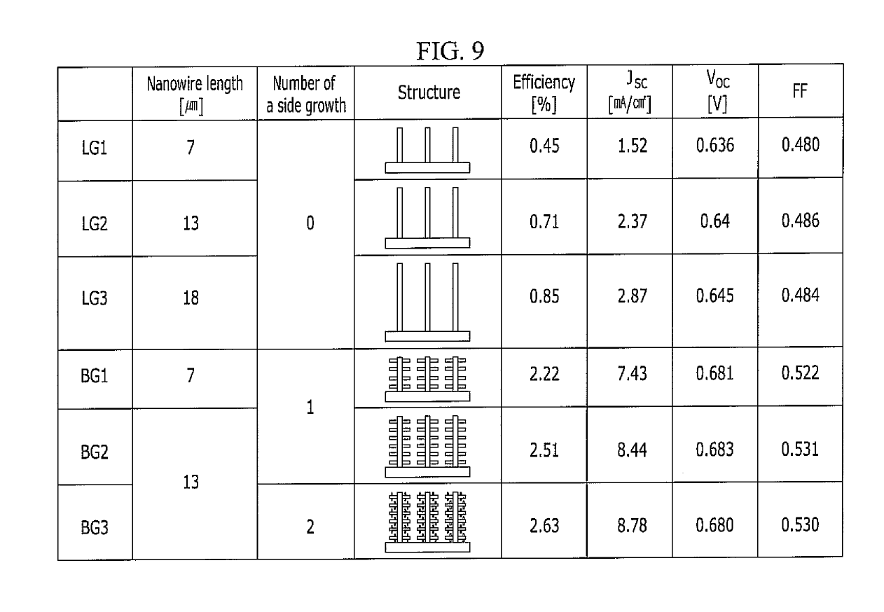

FIG. 8 is a view of curves of an open circuit voltage (V) and a short circuit current density (J) of a solar cell according to an exemplary embodiment of the present invention, and FIG. 9 is a view of a characteristic of a solar cell shown in FIG. 8.

As a variables determining the efficiency of the solar cell, there are an open circuit voltage (Voc), a short circuit current density (Jsc), a fill factor (FF), and efficiency (η).

The open voltage Voc is a potential difference between both terminals of the solar cell when receiving light in a state in which a circuit is opened, that is, an infinite impedance is applied, and the short circuit current density (Jsc) is a current density of a reverse direction (a negative value) in a state when the circuit is shorted, that is, an external resistance does not exist.

Also, the fill factor (FF) as a value of a product of the current density and the voltage value at a maximum power point divided by a product of the open circuit voltage (Voc) and the short circuit current density (Jsc), and is an index representing how the shape of a J-Va curve is close to a quadrangle in a state that light is applied, and the efficiency (η) of the solar cell is a ratio between maximum power produced by the solar cell and the incident light energy.

FIG. 8 and FIG. 9 show an axis direction growth LG1 of one time, the axis direction growth LG2 of two times, the axis direction growth LG3 of three times, a side growth BG1 of one time, the side growth BG2 of two times, the side growth BG3 of three times, a case LG in which the axis direction growth does not exist, and the open voltage Voc and the short circuit current density (Jsc) in a case BG that the side growth does not exist.

As shown in FIG. 8 and FIG. 9, as the axis direction growth and the side growth are progressed, it may be confirmed that the specific surface area of the solar cell is widened such that the efficiency (η) and the short circuit current density (Jsc) of the solar cell are increased. Also, it may be confirmed that the open voltage (Voc) and the fill factor (FF) are also increased.

As described above, the solar cell according to an exemplary embodiment of the present invention includes the photoelectrode 1000 made of the nanostructure 300 consisting of the nanowires 310, the nanobranches 320, and the sub-nanobranches 330 to maximally increase the specific surface area such that the dye deposition ratio and the light absorption ratio may be improved, thereby improving the energy conversion efficiency.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

### DESCRIPTION OF SYMBOLS

31: nano-seed layer
32: nano-shell layer
100: substrate
310: nanowires
320: nano-branches

What is claimed is:

1. A nanostructure comprising:
a plurality of nanowires formed at predetermined intervals on a substrate;
a plurality of nanobranches enclosing side surfaces of the nanowires; and
a plurality of sub-nanobranches enclosing side surfaces of the nanobranches.

2. The nanostructure of claim 1, wherein
the nanowires, the nanobranches, and the sub-nanobranches include zinc oxide.

3. The nanostructure of claim 1, wherein
the nanowires are formed in a direction perpendicular to the surface of the substrate.

4. The nanostructure of claim 1, wherein
the nanobranches are formed by removing a polymer from the nanowires and by progressing a hydrothermal reaction, and the nanobranches are extended in the side direction of the nanowire.

5. The nanostructure of claim 1, wherein
the sub-nanobranches are formed by repeating the hydrothermal reaction, and the sub-nanobranches are extended in the side direction of the nanobranches.

6. A method for manufacturing a nanostructure, comprising:
adhering a plurality of first nanoparticles on a substrate to form a nanoseed layer;
growing the nanoseed layer on the substrate to form a plurality of nanowires;
adhering a plurality of second nanoparticles to the side surface of the nanowires to form a nanoshell layer; and
growing the nanoshell layer to form a plurality of nanobranches.

7. The method of claim 6, wherein
the forming of the nanoseed layer includes:
filling a seed solution including a plurality of first nanoparticles into a seed container; and
positioning a substrate inside the seed container to form the nanoseed layer on the substrate.

8. The method of claim 6, wherein
the forming of the nanowires includes:
soaking the substrate formed with the nanoseed layer in a precursor solution including the polymer; and
progressing a hydrothermal reaction for the nanoseed layer.

9. The method of claim 8, wherein
a plurality of nanowires are formed at predetermined intervals on the substrate.

10. The method of claim 8, further comprising
removing the polymer from the nanowires after forming a plurality of nanowires.

11. The method of claim 10, wherein
the nanowires are heated to remove the polymer.

12. The method of claim 8, wherein
the nanobranches are formed by growing the nanoshell layer in the side surface of the nanowires.

13. The method of claim 10, further comprising
progressing a hydrothermal reaction for the nanobranches to form a plurality of sub-nanobranches at the side surface of the nanobranches.

14. A solar cell comprising:
a photoelectrode made of a nanostructure including a plurality of nanowires formed at predetermined intervals on a substrate, a plurality of nanobranches enclosing the side surface of the nanowires, a plurality of sub-nanobranches enclosing the side surface of the nanobranches, and a dye absorbed to the photoelectrode;
an opposite electrode facing the photoelectrode; and
an electrolyte positioned between the photoelectrode and the opposite electrode.

15. The solar cell of claim 14, wherein
the nanowires, the nanobranches, and the sub-nanobranches include zinc oxide.
